(19) United States
(12) Patent Application Publication
(10) Pub. No.: US 2025/0266115 A1
(43) Pub. Date: Aug. 21, 2025

(54) DIE-ON-HOLD FLAG

(71) Applicant: Micron Technology, Inc., Boise, ID (US)

(72) Inventor: Tieniu Li, San Jose, CA (US)

(21) Appl. No.: 19/053,096

(22) Filed: Feb. 13, 2025

Related U.S. Application Data
(60) Provisional application No. 63/553,834, filed on Feb. 15, 2024.

(51) Int. Cl. G11C 29/02; G11C 16/20; G11C 29/52

(52) U.S. Cl. CPC G11C 29/022; G11C 16/20; G11C 29/52

(57) ABSTRACT

This disclosure configures a memory sub-system controller to dynamically set a die-on-hold flag. The controller computes one or more defectivity criteria associated with an individual memory component of the set of memory components. The controller determines that the defectivity criteria associated with an individual memory component satisfy one or more thresholds. The controller, in response to determining that the defectivity criteria satisfy a first set of thresholds, asserts a die-on-hold flag associated with the individual memory component to prevent programming operations from being performed on the individual memory component. The controller, in response to determining that a read trigger associated with the individual memory component satisfies a second set of thresholds, clears the die-on-hold flag to resume performing the programming operations on the individual memory component.

### PRIORITY APPLICATION

This application claims the benefit of priority to U.S. Provisional Application Ser. No. 63/553,834, filed Feb. 15, 2024, which is incorporated herein by reference in its entirety.

### TECHNICAL FIELD

Examples of the disclosure relate generally to memory sub-systems and, more specifically, to providing adaptive media management for memory components, such as memory dies.

### BACKGROUND

A memory sub-system can be a storage system, such as a solid-state drive (SSD), and can include one or more memory components that store data. The memory components can be, for example, non-volatile memory components and volatile memory components. In general, a host system can utilize a memory sub-system to store data on the memory components and to retrieve data from the memory components.

### BRIEF DESCRIPTION OF THE DRAWINGS

The present disclosure will be understood more fully from the detailed description given below and from the accompanying drawings of various examples of the disclosure.

FIG. 1 is a block diagram illustrating an example computing environment including a memory sub-system, in accordance with some examples.

FIGS. 2 and 3 are block diagrams of example sets of triggers used to perform adaptive media management operations, in accordance with some examples.

FIG. 4 is a flow diagram of an example method of performing adaptive media management operations, in accordance with some examples.

FIG. 5 is a block diagram illustrating a diagrammatic representation of a machine in the form of a computer system within which a set of instructions can be executed for causing the machine to perform any one or more of the methodologies discussed herein, in accordance with some examples.

### DETAILED DESCRIPTION

Examples of the present disclosure configure a system component, such as a memory sub-system controller, to perform one or more memory operations (e.g., die-on-hold operations) to prevent/allow programming operations on one or more memory dies based on one or more dynamically computed defectivity criteria. For example, the controller can compute one or more defectivity criteria associated with an individual memory component of a set of memory components, such as an individual memory die. The controller can then selectively assert a die-on-hold flag (or status indicator or semaphore) to prevent programming operations to be performed on the individual memory component based on whether the one or more defectivity criteria satisfy a first set of thresholds. The controller can clear the die-on-hold flag based on one or more triggers satisfying a second set of thresholds. The controller can also reduce the die-on-hold flag (since it can be an integer value) up on attempting to invoke a programming operation on the die, such that each attempted operation is counted as one on-hold unit and eventually the flag reaches zero, or cleared. This way, the memory component can be temporarily taken offline to prevent programming data while allowing reading of data based on dynamic factors specific to current operations of the one or more memory components, which improves the overall efficiency of the memory sub-system.

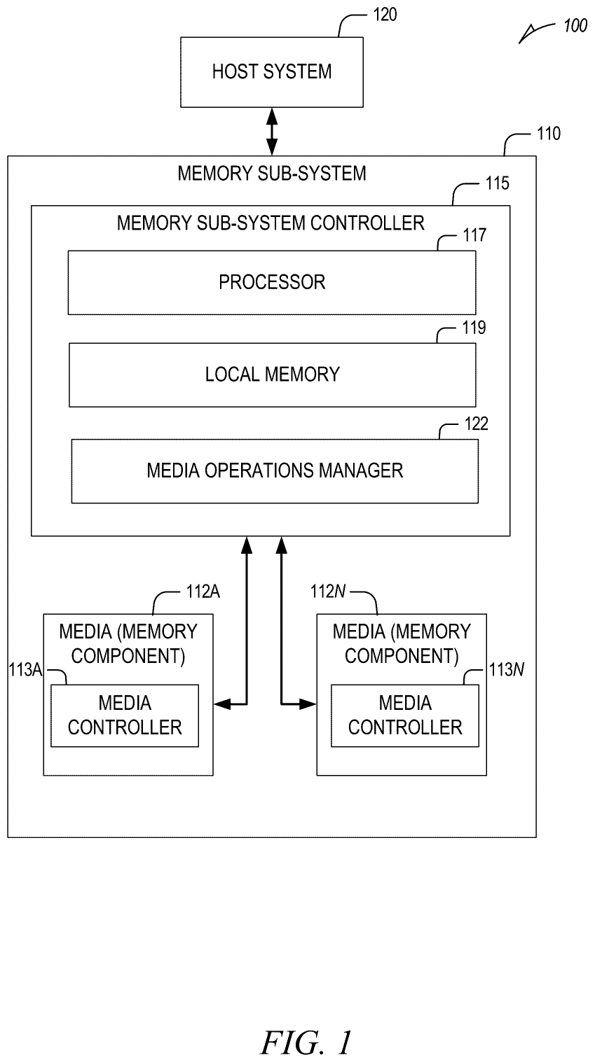

A memory sub-system can be a storage device, a memory module, or a hybrid of a storage device and memory module. Examples of storage devices and memory modules are described below in conjunction with FIG. 1. In general, a host system can utilize a memory sub-system that includes one or more memory components, such as memory devices (e.g., memory dies or planes across multiple memory dies) that store data. The host system can send access requests (e.g., write command, read command) to the memory sub-system, such as to store data at the memory sub-system and to read data from the memory sub-system. The data (or set of data) specified by the host is hereinafter referred to as “host data,” “application data,” or “user data.”

The memory sub-system can initiate media management operations, such as a write operation, on host data that is stored on a memory device. For example, firmware of the memory sub-system may re-write previously written host data from a location on a memory device to a new location as part of garbage collection management operations. The data that is re-written, for example as initiated by the firmware, is hereinafter referred to as “garbage collection data.” “User data” can include host data and garbage collection data. “System data” hereinafter refers to data that is created and/or maintained by the memory sub-system for performing operations in response to host requests and for media management. Examples of system data include, and are not limited to, system tables (e.g., logical-to-physical address mapping table), data from logging, scratch pad data, etc.

Many different media management operations can be performed on the memory device. For example, the media management operations can include different scan rates, different scan frequencies, different wear leveling, different read disturb management, different near miss error correction (ECC), and/or different dynamic data refresh. Media management operations can be performed on a per die basis, per block basis, per channel basis, and/or per plane basis to compute various defectivity criteria, such as an erase status fail (ESF) indicator, a program status fail (PSF) indicator, grown bad block (GBB) information, die bad block (DBB) information, read error handling (REH) information, and/or a select gate (SG) scan fail indicator. Wear leveling ensures that all blocks in a memory component approach their defined erase-cycle budget at the same time, rather than some blocks approaching it earlier. Read disturb management counts all of the read operations to the memory component. If a certain threshold is reached, the surrounding regions are refreshed. Near-miss ECC refreshes all data read by the application that exceeds a configured threshold of errors. Dynamic data-refresh scans read all data and identify the error status of all blocks as a background operation. If a certain threshold of errors per block or ECC unit is exceeded in this scan-read, a refresh operation is triggered.

A memory device can be a non-volatile memory device. A non-volatile memory device is a package of one or more dice (or dies). Each die can be comprised of one or more planes. For some types of non-volatile memory devices (e.g., negative-and (NAND) devices), each plane is comprised of a set of physical blocks. For some memory devices, blocks are the smallest area than can be erased. Such blocks can be referred to or addressed as logical units (LUN). Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND), which are raw memory devices combined with local embedded controllers for memory management within the same memory device package.

When certain portions of the memory components of conventional memory sub-systems start reaching their end of life, such as when a certain number (e.g., 1000) of program-erase (PE) cycles are performed on the portions, additional tests need to be performed to test the reliability of the portions. If the portions successfully pass the additional tests (e.g., SG scan operations), the portions are placed in a free block pool to allow data to be programmed to the portions. If the portions fail the additional tests (e.g., SG scan operations), the portions are marked bad to prevent data from being subsequently programmed to these portions. There are certain areas within each NAND block called SGD (select gate drain) and SGS (select gate source) that can have a charge loss as NAND undergoes multiple PE cycles. The SG scan operations can be performed to detect if this degradation has happened when the NAND block has reached each predefined erase cycle and/or when a certain default number of read operations have been performed on the NAND block and/or die.

As part of the SG scan operations, a low VT (voltage threshold) scan is performed on the SGS/SGD of a target block to test if the scan fails. If this scan fails, a voltage recovery operation can be performed to improve the health of the memory block. Then, a high VT scan is performed on the SGS/SGD of the target block to test if the scan fails. The combination of the low VT and high VT application to the target block to determine if the target block is operating within a desired voltage range enables the detection of memory blocks that are likely to fail and provides an indication or measure of reliability of the target block as results of the SG scan operations.

In some cases, the memory controllers determine a current measure of GBB information associated with a memory portion or component (e.g., a memory die) corresponds to a predefined default threshold. If so, the memory controller can prevent future writes to the memory portion or component. The default threshold is usually set at device manufacture and may not meet the specific demands of the host systems on which the device is implemented. This one-size-fits all approach fails to address the needs of every system and can be overly conservative or not conservative enough, which results in poor memory performance.

Examples of the present disclosure address the above and other deficiencies by providing a memory controller that can dynamically control when program operations are prevented from being performed on certain memory components (e.g., memory dies) based on one or more defectivity criteria, such as by setting the die-on-hold flag. The memory controller can monitor information from all types of failures including REH, erase, program, scan associated with the memory components to subsequently allow or disallow the program operations to be performed, by increasing or decreasing the value of the die-on-hold flag. In this way, the controller can improve the storage and retrieval of data from the memory components and reduce errors.

In some examples, the memory controller computes one or more defectivity criteria associated with an individual memory component of the set of memory components. The memory controller determines that the one or more defectivity criteria associated with an individual memory component satisfy one or more thresholds. The memory controller, in response to determining that the one or more defectivity criteria satisfy a first set of thresholds, asserts a die-on-hold flag associated with the individual memory component to prevent programming operations from being performed on the individual memory component. The memory controller, in response to determining that a read trigger associated with the individual memory component satisfies a second set of thresholds, clears the die-on-hold flag to resume performing the programming operations on the individual memory component.

In some cases, the one or more defectivity criteria are computed based on an ESF indicator, a PSF indicator, GBB information, DBB information, and a SG scan fail indicator. The SG scan fail indicator triggers an SG scan operation that monitors a threshold voltage associated with an SG source or SG drain of one or more memory cells of the individual memory component. The GBB information represents a quantity of blocks within a memory plane or stripe that have failed, wherein the DBB indicates whether the individual memory component includes one or more GBBs.

The defectivity criteria can be computed based on back-to-back error information including the ESF indicator, a PSF indicator, GBB information, DBB information, and/or the SG scan fail indicator. In some cases, the read trigger is computed based on REH information, program pass information, and/or erase pass information.

The memory controller determines that GBB information of the defectivity criteria has reached a GBB threshold. The memory controller, in response to determining that the GBB information of the defectivity criteria has reached the GBB threshold, permanently asserts the die-on-hold flag. In some cases, a separate die-on-hold flag is maintained for each of the set of memory components.

The memory controller tracks a quantity of PSF indicators associated with the individual memory component. The memory controller then tracks a quantity of program pass indicators associated with the individual memory component. The memory controller computes a portion of the defectivity criteria based on the quantity of PSF indicators and the quantity of program pass indicators.

In some cases, the memory controller determines a number of PSF indicators on an individual block stripe of the individual memory component to compute GBB information. The memory controller reduces the GBB information based on the quantity of program pass indicators.

The memory controller counts the number of GBB information per single plane of the individual memory component over multiple block stripes. The number of GBB information associated with a first block stripe of the individual memory component is combined with the number of GBB information associated with a second block stripe of the individual memory component. The number of GBB information is reset each time the die-on-hold flag is asserted.

In some examples, the memory controller counts the number of GBB information for multiple planes of the individual memory component over multiple block stripes. The number of GBB information associated with a first plane of the individual block stripe can be combined with the number of GBB information associated with a second plane of the individual block stripe. The memory controller can count the number of GBB information for multiple dies including the individual memory component. In some cases, the number of GBB information can be reset every threshold number of times that the die-on-hold flag is asserted.

The die-on-hold flag can be asserted in response to determining that the GBB information transgresses a GBB threshold. The one or more defectivity criteria can be computed as a ratio of the quantity of PSF indicators and the quantity of program pass indicators. In some cases, a state of the die-on-hold flag can be cleared during power cycling of the memory sub-system.

Though various examples are described herein as being implemented with respect to a memory sub-system (e.g., a controller of the memory sub-system), some or all of the portions of an example can be implemented with respect to a host system, such as a software application or an operating system of the host system.

FIG. 1 illustrates an example computing environment 100 including a memory sub-system 110, in accordance with some examples. The memory sub-system 110 can include media, such as memory components 112A to 112N (also hereinafter referred to as “memory devices”). The memory components 112A to 112N can be volatile memory devices, non-volatile memory devices, or a combination of such. The memory components 112A to 112N can be implemented by individual dies, such that a first memory component 112A can be implemented by a first memory die (or a first collection of memory dies) and a second memory component 112N can be implemented by a second memory die (or a second collection of memory dies). Each memory die can include a plurality of planes in which data can be stored or programmed. In some cases, the first memory component 112A can be implemented by a first SSD (or a first independently operable memory sub-system) and the second memory component 112N can be implemented by a second SSD (or a second independently operable memory sub-system). In some cases, each of the memory components 112A to 112N is associated with a respective one of LUNG-N. For example, the first memory component 112A can be associated with a first LUN (referred to as LUN0) and the second memory component 112N can be associated with a second LUN (referred to as LUN1).

In some examples, the memory sub-system 110 is a storage system. A memory sub-system 110 can be a storage device, a memory module, or a hybrid of a storage device and memory module. Examples of a storage device include a SSD, a flash drive, a universal serial bus (USB) flash drive, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and a non-volatile dual in-line memory module (NVDIMM).

The computing environment 100 can include a host system 120 that is coupled to a memory system. The memory system can include one or more memory sub-systems 110. In some examples, the host system 120 is coupled to different types of memory sub-systems 110. FIG. 1 illustrates one example of a host system 120 coupled to one memory sub-system 110. The host system 120 uses the memory sub-system 110, for example, to write (program) data to the memory sub-system 110 and read (retrieve) data from the memory sub-system 110. As used herein, “coupled to” generally refers to a connection between components, which can be an indirect communicative connection or direct communicative connection (e.g., without intervening components), whether wired or wireless, including connections such as electrical, optical, magnetic, etc.

The host system 120 can be a computing device such as a desktop computer, laptop computer, network server, mobile device, embedded computer (e.g., one included in a vehicle, industrial equipment, or a networked commercial device), or such computing device that includes a memory and a processing device. The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL), a USB interface, a Fibre Channel interface, a Serial Attached SCSI (SAS) interface, etc. The physical host interface can be used to transmit data between the host system 120 and the memory sub-system 110. The host system 120 can further utilize an NVM Express (NVMe) interface to access the memory components 112A to 112N when the memory sub-system 110 is coupled with the host system 120 by the PCIe or CXL interface. The physical host interface can provide an interface for passing control, address, data, and other signals between the memory sub-system 110 and the host system 120.

The memory components 112A to 112N can include any combination of the different types of non-volatile memory components and/or volatile memory components and/or storage devices. An example of non-volatile memory components include a NAND-type flash memory. Each of the memory components 112A to 112N can include one or more arrays of memory cells such as single-level cells (SLCs) or multi-level cells (MLCs) (e.g., tri-level cells (TLCs) or quad-level cells (QLCs)). In some examples, a particular memory component 112 can include both an SLC portion and an MLC portion of memory cells. Each of the memory cells can store one or more bits of data (e.g., blocks) used by the host system 120. Although non-volatile memory components such as NAND-type flash memory are described, the memory components 112A to 112N can be based on any other type of memory, such as a volatile memory. In some examples, the memory components 112A to 112N can be, but are not limited to, random access memory (RAM), read-only memory (ROM), dynamic random access memory (DRAM), synchronous dynamic random access memory (SDRAM), phase change memory (PCM), magnetoresistive random access memory (MRAM), negative-or (NOR) flash memory, electrically erasable programmable read-only memory (EEPROM), and a cross-point array of non-volatile memory cells.

A cross-point array of non-volatile memory cells can perform bit storage based on a change of bulk resistance in conjunction with a stackable cross-gridded data access array. Additionally, in contrast to many flash-based memories, cross-point non-volatile memory can perform a write-in-place operation, where a non-volatile memory cell can be programmed without the non-volatile memory cell being previously erased. Furthermore, the memory cells of the memory components 112A to 112N can be grouped as memory pages or blocks that can refer to a unit of the memory component 112 used to store data. For example, a single first row that spans a first set of the pages or blocks of the memory components 112A to 112N can correspond to or be grouped as a first block stripe and a single second row that spans a second set of the pages or blocks of the memory components 112A to 112N can correspond to or be grouped as a second block stripe. A single block stripe can be associated with multiple LUNs (e.g., LUN0-N).

A memory sub-system controller 115 can communicate with the memory components 112A to 112N to perform memory operations such as reading data, writing data, or erasing data at the memory components 112A to 112N and other such operations. The memory sub-system controller 115 can communicate with the memory components 112A to 112N to perform various memory management operations, such as enhancement operations, different scan rates, SG scan operations, different scan frequencies, different wear leveling, different read disturb management, garbage collection operations, different near miss ECC operations, and/or different dynamic data refresh. The SG scan operations can be performed to test reliability of a portion or the entirety of a block stripe or portion being tested and/or one or more memory dies. The SG scan operation can apply high and/or low VT voltages to the portion being tested to determine whether the output corresponds to an expected range and/or to modify a VT of the corresponding portions. A result of the SG scan operation can be indicative of failure of the portion being tested, and if the portion fails the SG scan operation, the portion being tested and/or the entire block stripe that includes the portion being tested can be marked bad to prevent future writes to the portion and/or block stripe.

Various other types of failure indicators (or failure triggers) can be monitored and tracked on a per-die basis, per-block basis, per-channel basis, and/or per-plane basis. These failure triggers can include any combination of ESF indicators, PSF indicators, GBB information, DBB information, and/or SG scan fail indicators. These failure triggers can be combined or tracked to generate one or more defectivity criteria for each memory component 112A to 112N and/or block, channel, plane, page, and so forth. The memory sub-system controller 115 can determine whether the defectivity criteria satisfy a first set of thresholds (e.g., if the GBB for a certain memory component 112A to 112N, block, channel, plane, and so forth transgresses a maximum value). In such cases, the memory sub-system controller 115 can assert a die-on-hold flag. The die-on-hold flag, when asserted, prevents programming new data to the associated memory component 112A to 112N, block, channel, and/or plane on a temporary basis or permanent basis. Namely, the die-on-hold flag, when asserted and set to a value that transgresses a maximum value, can never be cleared and is set permanently. If the die-on-hold flag is asserted and set to a value below the maximum value, the die-on-hold flag can be cleared when other conditions are met, such as if read trigger information satisfies a second set of thresholds. This allows the memory sub-system controller 115 to temporarily or permanently and dynamically take certain memory components 112A to 112N, blocks, channels, and/or planes offline to prevent writing new data but continue to allow reading data.

The memory sub-system controller 115 can include hardware, such as one or more integrated circuits and/or discrete components, a buffer memory, or a combination thereof. The memory sub-system controller 115 can be a microcontroller, special-purpose logic circuitry (e.g., a FPGA, an ASIC, etc.), or another suitable processor. The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120. In some examples, the local memory 119 can include memory registers storing memory pointers, fetched data, and so forth. The local memory 119 can also include ROM for storing microcode. While the example memory sub-system 110 in FIG. 1 has been illustrated as including the memory sub-system controller 115, in another example of the present disclosure, a memory sub-system 110 may not include a memory sub-system controller 115, and can instead rely upon external control (e.g., provided by an external host, or by a processor 117 or controller separate from the memory sub-system 110).

In general, the memory sub-system controller 115 can receive commands or operations from the host system 120 and can convert the commands or operations into instructions or appropriate commands to achieve the desired access to the memory components 112A to 112N. In some examples, the commands or operations received from the host system 120 can specify configuration data for the memory components 112A to 112N. The configuration data can describe the lifetime (maximum) program-erase count (PEC) values and/or reliability grades associated with different groups of the memory components 112A to 112N and/or different blocks within each of the memory components 112A to 112N. The configuration data can also include various manufacturing information for individual memory components of the memory components 112A to 112N. The manufacturing information can specify the reliability metrics/information associated with each memory component. For example, the configuration data can specify the first set of thresholds that control when one or more defectivity criteria causes a die-on-hold flag to be asserted. The configuration data can specify the second set of thresholds that control when one or more read triggers cause a die-on-hold flag to be cleared to allow resumption of writing data to the corresponding memory components 112A to 112N, plane, block, and/or channel.

Depending on the example, a media operations manager 122 can comprise logic (e.g., a set of transitory or non-transitory machine instructions, such as firmware) or one or more components that causes the media operations manager 122 to perform operations described herein. The media operations manager 122 can comprise a tangible or non-tangible unit capable of performing operations described herein. Further details with regards to the operations of the media operations manager 122 are described below.

In some examples, the media operations manager 122 computes one or more defectivity criteria associated with an individual memory component of the set of memory components. The media operations manager 122 determines that the defectivity criteria associated with an individual memory component satisfy one or more thresholds. The media operations manager 122, in response to determining that the defectivity criteria satisfy the first set of thresholds, asserts a die-on-hold flag associated with the individual memory component to prevent programming operations from being performed on the individual memory component. The media operations manager 122, in response to determining that a read trigger associated with the individual memory component satisfies the second set of thresholds, clears the die-on-hold flag to resume performing the programming operations on the individual memory component.

In some examples, the commands or operations received from the host system 120 can include a write/read command, which can specify or identify an individual memory component (e.g., memory die) in which to program/read data. Based on the memory component specified by the write/read command, the memory sub-system controller 115 can program/read the data into/from one or more of the memory components 112A to 112N. The memory sub-system controller 115 can be responsible for other memory management operations, such as wear leveling operations, garbage collection operations, error detection and ECC operations, encryption operations, caching operations, and address translations. The memory sub-system controller 115 can further include host interface circuitry to communicate with the host system 120 via the physical host interface. The host interface circuitry can convert the commands received from the host system 120 into command instructions to access the set of memory components 112A to 112N as well as convert responses associated with the set of memory components 112A to 112N into information for the host system 120.

The memory sub-system 110 can also include additional circuitry or components that are not illustrated. In some examples, the memory sub-system 110 can include a cache or buffer (e.g., DRAM or other temporary storage location or device) and address circuitry (e.g., a row decoder and a column decoder) that can receive an address from the memory sub-system controller 115 and decode the address to access the set of memory components 112A to 112N.

The memory devices can be raw memory devices (e.g., NAND), which are managed externally, for example, by an external controller (e.g., memory sub-system controller 115). The memory devices can be managed memory devices (e.g., managed NAND), which are raw memory devices combined with a local embedded controller (e.g., local media controllers) for memory management within the same memory device package. Any one of the set of memory components 112A to 112N can include a media controller (e.g., media controller 113A and media controller 113N) to manage the memory cells of the memory component (e.g., to perform one or more memory management operations), to communicate with the memory sub-system controller 115, and to execute memory requests (e.g., read or write) received from the memory sub-system controller 115.

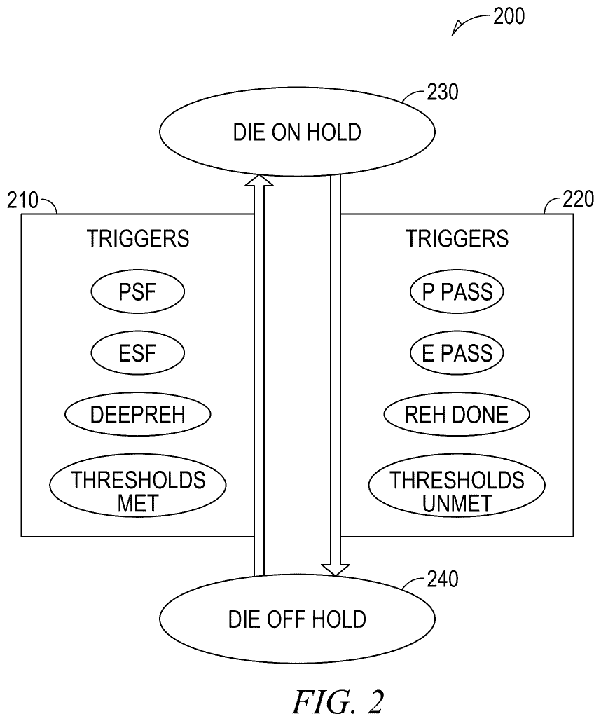

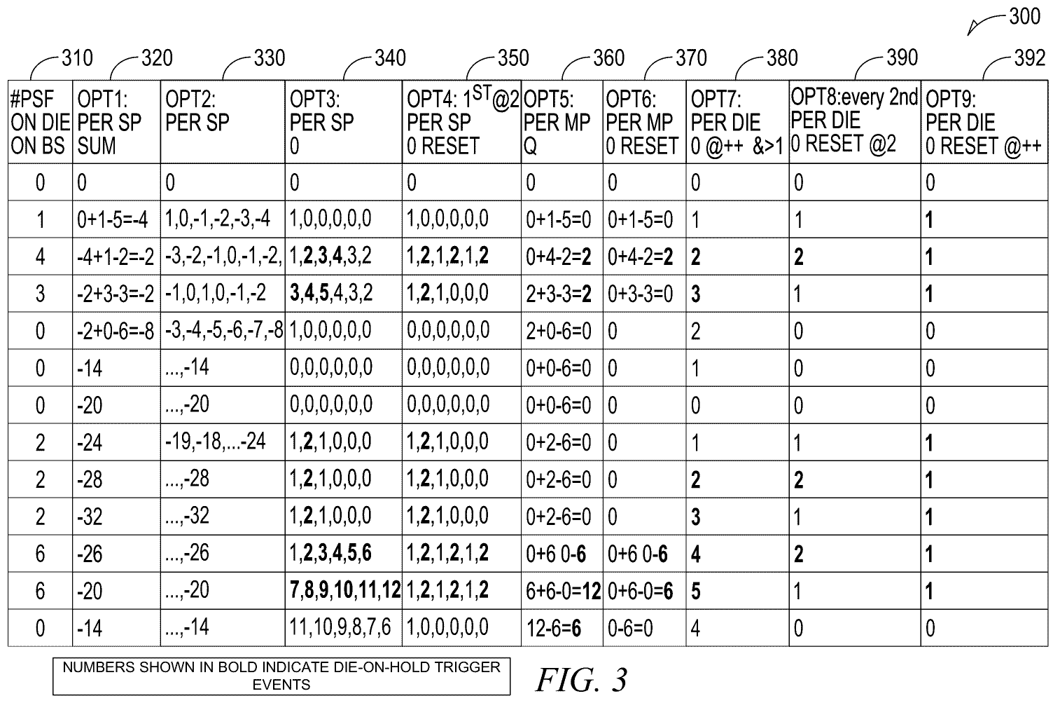

FIGS. 2 and 3 are block diagrams 200 and 300 of example sets of triggers used to perform adaptive media management operations, in accordance with some examples. For example, as shown in diagram 200, the media operations manager 122 can dynamically assert/clear a die-on-hold flag to temporarily or permanently prevent future writes to a corresponding memory component in the set of memory components 112A to 112N. Specifically, the media operations manager 122 can monitor a plurality of triggers 210 (e.g., data program triggers) associated with the memory component. This plurality of triggers 210 can include ESF indicators, a PSF indicators, GBB information, DBB information, and/or a SG scan fail indicators. The media operations manager 122 can generate defectivity criteria based on the plurality of triggers 210.

The media operations manager 122 can continuously or periodically compare the defectivity criteria to a first set of thresholds. In response to determining that the defectivity criteria satisfy the first set of thresholds, the media operations manager 122 can assert a die-on-hold flag 230. When the die-on-hold flag 230 is asserted, the media operations manager 122 is prevented from programming new data to the corresponding memory component. While certain examples are provided with respect to the die-on-hold flag 230 preventing programming new data to a memory component, similar techniques can be applied to assert a flag to prevent programming new data to a portion of a memory component, such as a channel, plane, page, and/or block, when the defectivity criteria satisfy the first set of thresholds.

The media operations manager 122 can monitor a plurality of read triggers 220. These plurality of read triggers 220 include program pass triggers (which indicate whether data has successfully been programmed to the memory component), erase pass triggers (which indicate whether the memory component or region of the memory component has successfully been erased), whether REH has been performed (and how often or how many times the REH has been performed for the memory component), and so forth. The media operations manager 122 can continuously or periodically compare the plurality of read triggers 220 to a second set of thresholds. In response to determining that the plurality of read triggers 220 satisfy the second set of thresholds, the media operations manager 122 can perform operation 240 to clear (de-assert) the die-on-hold flag 230 (e.g., by asserting a die-off-hold flag 230). When the die-on-hold flag 230 is cleared, the media operations manager 122 is resumes programming new data to the corresponding memory component.

There are various ways to generate the defectivity criteria from the plurality of triggers 210. Some of these various ways are explained with respect to diagram 300, shown in FIG. 3. For example, the media operations manager 122 can maintain a running count of the GBB for a memory component. The GBB count can be incremented each time an ESF, PSF, and/or SGS (select gate scan) indicator is detected while programming or erasing data from a memory component or region of the memory component (e.g., block, page, channel, and/or plane). When the media operations manager 122 determines that the running count of the GBB reaches a maximum threshold, the media operations manager 122 permanent asserts the die-on-hold flag 230 by setting the die-on-hold flag 230 to the maximum value.

As another example, the media operations manager 122 can track consecutive PSF indicators to generate the defectivity criteria. Namely, the media operations manager 122 can generate or maintain a running count of the GBB for a memory component. The GBB count can be incremented each time a PSF indicator is detected while programming data in the memory component or a region of the memory component. The media operations manager 122 can decrement the GBB count each time a program pass indicator is detected while programming data in the memory component or a region of the memory component. When the media operations manager 122 determines that the running count of the GBB reaches a maximum threshold, the media operations manager 122 temporarily asserts the die-on-hold flag 230 (setting the flag to a value below a maximum value). This can be performed if there exist less than two free block stripes and the GBB count is greater than two or some other threshold.

In some cases, the media operations manager 122 monitors the number of PSF indicators on a die and/or a block stripe indicted by the first column 310. If the media operations manager 122 determines that one PSF indicator is detected, the media operations manager 122 sums the PSF for the single plane, as shown in the second column 320. For example, the media operations manager 122 determines there exists one failed portion of the memory component and five good portions on the memory component based on the PSF indicator and/or the program pass indicators. In such cases, the media operations manager 122 computes the GBB as −4 (e.g., because the GBB count is incremented by one and decremented by 5 resulting in negative 4). Subsequently, the media operations manager 122 detects there exists four failed portions and two good portions. Now, the GBB count is adjusted by incrementing the running GBB count by four and decrementing by two, resulting in a total value of −2. This process continues as different locations or regions of the memory component are programmed over time until the GBB count reaches a threshold to control setting of the die-on-hold flag.

In some cases, the media operations manager 122 monitors the number of PSF indicators on a die and/or a block stripe indicted by the first column 310. If the media operations manager 122 determines that one PSF indicator is detected, the media operations manager 122 sums the PSF for the single plane, as shown in the third column 330. The media operations manager 122 can maintain and update the count as each block on the memory component is programmed to provide a more detailed view of the PSF indicators that are detected.

In some examples, as shown in the fourth column 340, the media operations manager 122 prevents the GBB count from falling below zero. This allows the GBB count to reach the threshold quicker to trigger the die-on-hold flag to be set. In some examples, as shown in the fifth column 350, the media operations manager 122 prevents the GBB count from falling below zero but also triggers or sets the die-on-hold flag when the GBB count reaches the first even number, such as 2. When the die-on-hold flag is subsequently cleared, the GBB count is reset back to 0 and counting resumes to trigger the die-on-hold flag again when the count reaches the even number. In some cases, this takes the corresponding memory component offline to prevent programming but allowing reading for one cycle or one time. This can be performed for only a single plane or on a single plane basis. Namely, the GBB count is maintained for each plane of the memory component.

In some examples, as shown in the sixth column 360, the media operations manager 122 prevents the GBB count from falling below zero but also triggers or sets the die-on-hold flag when the GBB count reaches the first even number, such as 2 for multiple planes. Namely, a single GBB count is maintained for multiple planes of the memory component rather than having multiple GBB counts for each plane of the memory component, as in the fifth column 350. When the die-on-hold flag is triggered or set based on the GBB count reaching the threshold, the GBB count is not cleared or reset. In some cases, the media operations manager 122 resets the GBB count, as shown in the seventh column 370, when the die-on-hold flag is subsequently cleared. Because the GBB count is associated with and maintained for multiple planes in the sixth column 360, this causes the die-on-hold flag to be triggered fewer times than the fifth column 360.

In some circumstances, the media operations manager 122 maintains the GBB count on a per die basis rather than per plane. This is demonstrated by the GBB counts shown in columns 380, 390, and 392. For example, the media operations manager 122 can track across a particular die whether the GBB count is increasing. If the GBB count is increasing, then the media operations manager 122 asserts the die-on-hold flag temporarily. If the media operations manager 122 determines that the GBB count starts decreasing (e.g., because of the program pass indicator reducing the GBB count), the media operations manager 122 clears the die-on-hold flag. In some cases, as shown in column 390, the GBB count is reset when the die-on-hold flag is cleared.

In some examples, the media operations manager 122 tracks bursting of the PSF to control asserting and clearing of the die-on-hold flag. For example, the media operations manager 122 can maintain two separate counters for each memory component and/or plane. A first counter can represent a quantity of PSF indicators that are detected (e.g., triggered) and a second counter can represent a quantity of program pass indicators that are detected (e.g., triggered). The first counter can be incremented each time a PSF indicator is detected and the second counter is incremented each time the program pass indicator is detected. The media operations manager 122 can trigger or assert the die-on-hold flag in response to a ratio between the first and second counters. For example, if the first counter is greater than a threshold (e.g., 2) and a ratio of the first and second counters is greater than a threshold, then the die-on-hold flag is asserted. In some cases, the media operations manager 122 can dynamically adjust a threshold that is used to set the value of the die-on-hold flag to control whether the die-on-hold flag is set permanently or temporarily. Namely, the die-on-hold flag can be set to a value that corresponds to a predetermined threshold (Th)*the first counter*(the second counter+1). When the die-on-hold flag reaches a maximum value, the die-on-hold flag is permanently set. Otherwise, the die-on-hold flag is temporarily set and cleared subsequently based on REH or read triggers satisfying the second threshold.

In some examples, the value for the die-on-hold flag can be incremented by a value n that is computed as a function of the first and second counters. Once the die-on-hold flag reaches a threshold value, the die-on-hold flag is permanently set or is temporarily asserted and cleared based on subsequent read triggers. For example, the die-on-hold flag can be computed as a function corresponding to n=K*the first counter/(the second counter+1)−the previous value of n. K can be any integer constant value, such as the value one.

In some examples, the media operations manager 122 tracks a length of the queue of REH. Each time REH is triggered by a particular memory component read operation, the read operation enters the REH queue. A counter can be maintained representing the length of the REH queue. The die-on-hold flag can be incremented when the counter representing the length of the REH queue reaches an individual REH threshold. The die-on-hold flag can be decremented when the counter representing the length of the REH queue is below the individual REH threshold. Namely, when the counter reaches the individual REH threshold value, the die-on-hold flag is incremented for each subsequent REH queue operation (e.g., when a trigger queues up another read operation in the REH queue). When the counter is below the individual REH threshold value, the die-on-hold flag is decremented for each subsequent REH queue operation (e.g., when a trigger de-queues another read operation from the REH queue). The die-on-hold flag is temporarily set and cleared subsequently based on REH or read triggers satisfying the second threshold.

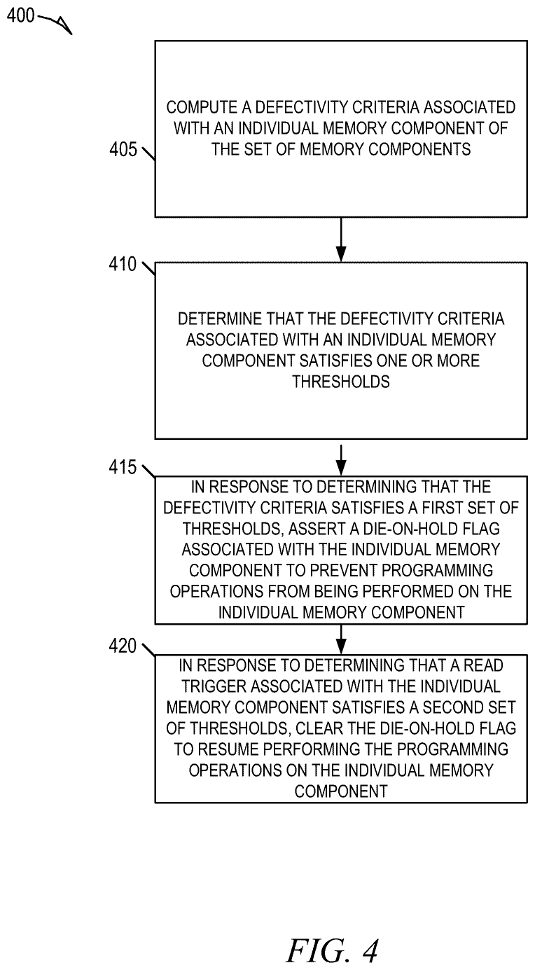

FIG. 4 is a flow diagram of an example method 400 for performing adaptive media management operations, in accordance with some examples. The method 400 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method 400 is performed by the media operations manager 122 of FIG. 1. Although the processes are shown in a particular sequence or order, unless otherwise specified, the order of the processes can be modified. Thus, the illustrated examples should be understood only as examples, and the illustrated processes can be performed in a different order, and some processes can be performed in parallel. Additionally, one or more processes can be omitted in various examples. Thus, not all processes are required in every example. Other process flows are possible.

Referring now to FIG. 4, the method 400 (or process) begins at operation 405, with a media operations manager 122 of a memory sub-system (e.g., memory sub-system 110) computing one or more defectivity criteria associated with an individual memory component of a set of memory components. Then, at operation 410, the media operations manager 122 determines that the one or more defectivity criteria associated with an individual memory component satisfy one or more thresholds and, at operation 415, in response to determining that the one or more defectivity criteria satisfy a first set of thresholds, asserts a die-on-hold flag associated with the individual memory component to prevent programming operations from being performed on the individual memory component. At operation 420, the media operations manager 122, in response to determining that a read trigger associated with the individual memory component satisfies a second set of thresholds, clears the die-on-hold flag to resume performing the programming operations on the individual memory component.

In view of the disclosure above, various examples are set forth below. It should be noted that one or more features of an example, taken in isolation or combination, should be considered within the disclosure of this application.

Example 1. A system comprising: a set of memory components of a memory sub-system; and at least one processing device operatively coupled to the set of memory components, the at least one processing device being configured to perform operations comprising: computing one or more defectivity criteria associated with an individual memory component of the set of memory components; determining that the one or more defectivity criteria associated with an individual memory component satisfy one or more thresholds; in response to determining that the one or more defectivity criteria satisfy a first set of thresholds, asserting a die-on-hold flag associated with the individual memory component to prevent programming operations from being performed on the individual memory component; and in response to determining that a read trigger associated with the individual memory component satisfies a second set of thresholds, clearing the die-on-hold flag to resume performing the programming operations on the individual memory component.

Example 2. The system of Example 1, wherein the one or more defectivity criteria are computed based on an ESF indicator, a PSF indicator, GBB information, DBB information, and a SG scan fail indicator.

Example 3. The system of Example 2, wherein the SG scan fail indicator triggers an SG scan operation that monitors a threshold voltage associated with an SG source or SG drain of one or more memory cells of the individual memory component.

Example 4. The system of any one of Examples 2-3, wherein the GBB information represents a quantity of blocks within a memory plane or stripe that have failed, and wherein the DBB indicates whether the individual memory component includes one or more GBBs.

Example 5. The system of any one of Examples 2-4, wherein the defectivity criteria is computed based on back-to-back error information comprising the ESF indicator, a PSF indicator, GBB information, DBB information, and the SG scan fail indicator.

Example 6. The system of any one of Examples 1-5, wherein the read trigger is computed based on REH information, program pass information, and erase pass information.

Example 7. The system of any one of Examples 1-6, the operations comprising: determining that GBB information of the defectivity criteria has reached a GBB threshold; and in response to determining that the GBB information of the defectivity criteria has reached the GBB threshold, permanently asserting the die-on-hold flag.

Example 8. The system of any one of Examples 1-7, wherein a separate die-on-hold flag is maintained for each of the set of memory components.

Example 9. The system of any one of Examples 1-8, the operations comprising: tracking a quantity of PSF indicators associated with the individual memory component; tracking a quantity of program pass indicators associated with the individual memory component; and computing a portion of the defectivity criteria based on the quantity of PSF indicators and the quantity of program pass indicators.

Example 10. The system of Example 9, the operations comprising: determining a number of PSF indicators on an individual block stripe of the individual memory component to compute GBB information; and reducing the GBB information based on the quantity of program pass indicators.

Example 11. The system of Example 10, the operations comprising: counting the number of GBB information per single plane of the individual memory component over multiple block stripes, wherein the number of GBB information associated with a first block stripe of the individual memory component is combined with the number of GBB information associated with a second block stripe of the individual memory component.

Example 12. The system of any one of Examples 10-11, wherein the number of GBB information is reset each time the die-on-hold flag is asserted.

Example 13. The system of any one of Examples 10-12, the operations comprising: counting the number of GBB information for multiple planes of the individual memory component over multiple block stripes, wherein the number of GBB information associated with a first plane of the individual block stripe is combined with the number of GBB information associated with a second plane of the individual block stripe.

Example 14. The system of any one of Examples 10-13, the operations comprising: counting the number of GBB information for multiple dies comprising the individual memory component.

Example 15. The system of Example 14, wherein the number of GBB information is reset every threshold number of times that the die-on-hold flag is asserted.

Example 16. The system of any one of Examples 10-15, wherein the die-on-hold flag is asserted in response to determining that the GBB information transgresses a GBB threshold.

Example 17. The system of any one of Examples 9-16, wherein the one or more defectivity criteria are computed as a ratio of the quantity of PSF indicators and the quantity of program pass indicators.

Example 18. The system of any one of Examples 1-17, wherein a state of the die-on-hold flag is cleared during power cycling of the memory sub-system.

Methods and computer-readable storage medium with instructions for performing any one of the above Examples.

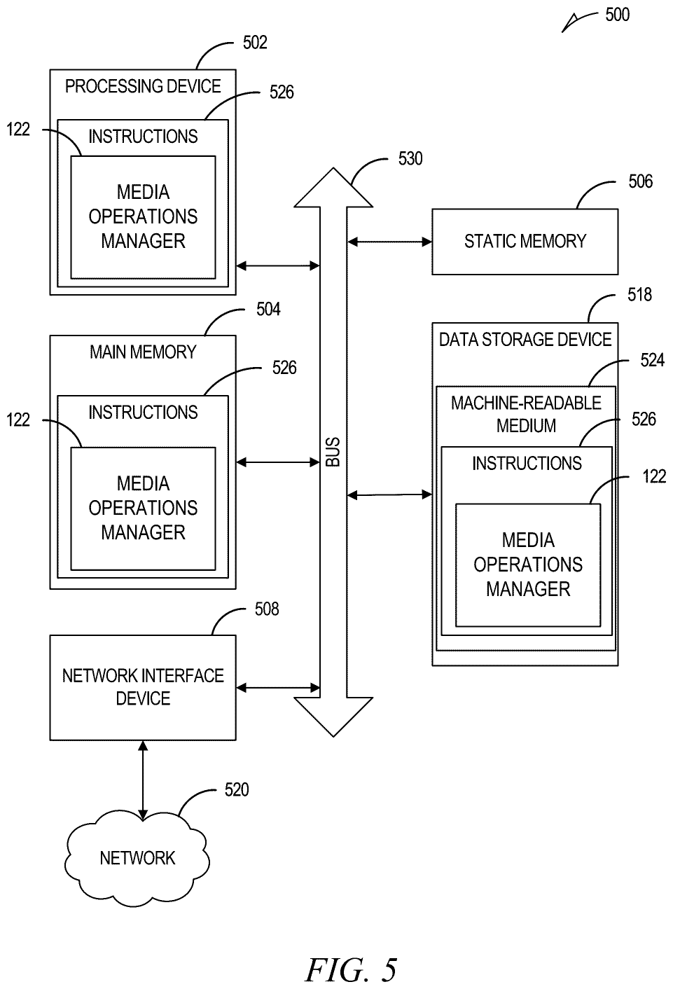

FIG. 5 illustrates an example machine in the form of a computer system 500 within which a set of instructions can be executed for causing the machine to perform any one or more of the methodologies discussed herein. In some examples, the computer system 500 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the media operations manager 122 of FIG. 1). In alternative examples, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a network switch, a network bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., ROM, flash memory, DRAM such as SDRAM or Rambus DRAM (RDRAM), etc.), a static memory 506 (e.g., flash memory, static random access memory (SRAM), etc.), and a data storage system 518, which communicate with each other via a bus 530.

The processing device 502 represents one or more general-purpose processing devices such as a microprocessor, a central processing unit, or the like. More particularly, the processing device 502 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 502 can also be one or more special-purpose processing devices such as an ASIC, a FPGA, a digital signal processor (DSP), a network processor, or the like. The processing device 502 is configured to execute instructions 526 for performing the operations and steps discussed herein. The computer system 500 can further include a network interface device 508 to communicate over a network 520.

The data storage system 518 can include a machine-readable storage medium 524 (also known as a computer-readable medium) on which is stored one or more sets of instructions 526 or software embodying any one or more of the methodologies or functions described herein. The instructions 526 can also reside, completely or at least partially, within the main memory 504 and/or within the processing device 502 during execution thereof by the computer system 500, the main memory 504 and the processing device 502 also constituting machine-readable storage media. The machine-readable storage medium 524, data storage system 518, and/or main memory 504 can correspond to the memory sub-system 110 of FIG. 1.

In one example, the instructions 526 implement functionality corresponding to the media operations manager 122 of FIG. 1. While the machine-readable storage medium 524 is shown in an example to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to convey the substance of their work most effectively to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system's memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks; ROMs; RAMs; erasable programmable read-only memories (EPROMs); EEPROMs; magnetic or optical cards; or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description above. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some examples, a machine-readable (e.g., computer-readable) medium includes a machine-readable (e.g., computer-readable) storage medium such as a ROM, RAM, magnetic disk storage media, optical storage media, flash memory components, and so forth.

In the foregoing specification, the disclosure has been described with reference to specific examples thereof. It will be evident that various modifications can be made thereto without departing from the broader scope of the disclosure as set forth in the following claims. The specification and drawings are, accordingly, to be regarded in an illustrative sense rather than a restrictive sense.

What is claimed is:

1. A system comprising:
a set of memory components of a memory sub-system; and
at least one processing device operatively coupled to the set of memory components, the at least one processing device configured to perform operations comprising:
computing one or more defectivity criteria associated with an individual memory component of the set of memory components;
determining that the one or more defectivity criteria associated with an individual memory component satisfy one or more thresholds;
in response to determining that the one or more defectivity criteria satisfy a first set of thresholds, asserting a die-on-hold flag associated with the individual memory component to prevent programming operations from being performed on the individual memory component; and
in response to determining that a read trigger associated with the individual memory component satisfies a second set of thresholds, clearing the die-on-hold flag to resume performing the programming operations on the individual memory component.

2. The system of claim 1, wherein the one or more defectivity criteria are computed based on an erase status fail (ESF) indicator, a program status fail (PSF) indicator, grown bad block (GBB) information, die bad block (DBB) information, and a select gate (SG) scan fail indicator.

3. The system of claim 2, wherein the SG scan fail indicator triggers an SG scan operation that monitors a threshold voltage associated with an SG source or SG drain of one or more memory cells of the individual memory component.

4. The system of claim 2, wherein the GBB information represents a quantity of blocks within a memory plane or stripe that have failed; and
wherein the DBB indicates whether the individual memory component includes one or more GBBs.

5. The system of claim 2, wherein the defectivity criteria is computed based on back-to-back error information comprising the ESF indicator, a PSF indicator, GBB information, DBB information, and the SG scan fail indicator.

6. The system of claim 1, wherein the read trigger is computed based on read error handling (REH) information, program pass information, and erase pass information.

7. The system of claim 1, the operations comprising:
determining that grown bad block (GBB) information of the defectivity criteria has reached a GBB threshold; and
in response to determining that the GBB information of the defectivity criteria has reached the GBB threshold, permanently asserting the die-on-hold flag.

8. The system of claim 1, wherein a separate die-on-hold flag is maintained for each memory component in the set of memory components.

9. The system of claim 1, the operations comprising:
tracking a quantity of program status fail (PSF) indicators associated with the individual memory component;
tracking a quantity of program pass indicators associated with the individual memory component; and
computing a portion of the defectivity criteria based on the quantity of PSF indicators and the quantity of program pass indicators.

10. The system of claim 9, the operations comprising:
determining a number of PSF indicators on an individual block stripe of the individual memory component to compute grown bad block (GBB) information; and
reducing the grown bad block (GBB) information based on the quantity of program pass indicators.

11. The system of claim 10, the operations comprising:
counting a number of GBB information per single plane of the individual memory component over multiple block stripes, wherein the number of GBB information associated with a first block stripe of the individual memory component is combined with the number of GBB information associated with a second block stripe of the individual memory component.

12. The system of claim 10, wherein a number of GBB information is reset each time the die-on-hold flag is asserted.

13. The system of claim 10, the operations comprising:
counting a number of GBB information for multiple planes of the individual memory component over multiple block stripes, wherein the number of GBB information associated with a first plane of the individual block stripe is combined with the number of GBB information associated with a second plane of the individual block stripe.

14. The system of claim 10, the operations comprising:
counting a number of GBB information for multiple dies comprising the individual memory component.

15. The system of claim 14, wherein the number of GBB information is reset every threshold number of times that the die-on-hold flag is asserted.

16. The system of claim 10, wherein the die-on-hold flag is asserted in response to determining that a value of the GBB information transgresses a GBB threshold.

17. The system of claim 9, wherein the one or more defectivity criteria are computed as a ratio of the quantity of PSF indicators and the quantity of program pass indicators.

18. The system of claim 1, wherein a state of the die-on-hold flag is cleared during power cycling of the memory sub-system.

19. A method comprising:
computing one or more defectivity criteria associated with an individual memory component of a set of memory components;
determining that the one or more defectivity criteria associated with an individual memory component satisfy one or more thresholds;
in response to determining that the one or more defectivity criteria satisfy a first set of thresholds, asserting a die-on-hold flag associated with the individual memory component to prevent programming operations from being performed on the individual memory component; and
in response to determining that a read trigger associated with the individual memory component satisfies a second set of thresholds, clearing the die-on-hold flag to resume performing the programming operations on the individual memory component.

20. A non-transitory computer-readable storage medium comprising instructions that, when executed by at least one processing device, cause the at least one processing device to perform operations comprising:
computing one or more defectivity criteria associated with an individual memory component of a set of memory components;
determining that the one or more defectivity criteria associated with an individual memory component satisfy one or more thresholds;
in response to determining that the one or more defectivity criteria satisfy a first set of thresholds, asserting a die-on-hold flag associated with the individual memory component to prevent programming operations from being performed on the individual memory component; and
in response to determining that a read trigger associated with the individual memory component satisfies a second set of thresholds, clearing the die-on-hold flag to resume performing the programming operations on the individual memory component.
